(19) United States
(12) Patent Application Publication
(10) Pub. No.: US 2025/0131139 A1
(43) Pub. Date: Apr. 24, 2025

(54) METHOD OF GENERATING DESIGN BASED ON USER PREFERENCE

(71) Applicant: IUCF-HYU (INDUSTRY-UNIVERSITY COOPERATION FOUNDATION HANYANG UNIVERSITY), Seoul (KR)

(72) Inventors: Kyung Hoon HYUN, Seoul (KR); Seung Won LEE, Goyang-si (KR); Jiin CHOI, Paju-si (KR)

(21) Appl. No.: 18/411,182

(22) Filed: Jan. 12, 2024

(30) Foreign Application Priority Data
Oct. 19, 2023 (KR) 10-2023-0140286
Nov. 16, 2023 (KR) 10-2023-0159030

(51) Int. Cl. G06F 30/13

(52) U.S. Cl. CPC G06F 30/13

(57) ABSTRACT

Provided is a method of generating a design preferred by a user using a navigation map for a reference design. The method of generating a design based on preference of a user includes: generating a navigation map for reference designs, the navigation map including points corresponding to latent vectors of the reference designs; estimating design preference of the user using a point selected by the user on the navigation map; and generating a design based on the design preference.

### CROSS-REFERENCE TO RELATED APPLICATION

This application claims priority under 35 U.S.C. § 119(a) to, and the benefit of, Korean Patent Application No. 2023-0140286, filed with the Korean Intellectual Property Office on Oct. 19, 2023, Korean Patent Application No. 2023-0159030, filed with the Korean Intellectual Property Office on Nov. 16, 2023. The disclosure of the above patent applications is incorporated herein by reference in its entirety.

### BACKGROUND

### 1. Field of the Invention

The present disclosure relates to a method of generating a design based on user preference, and more specifically, to a method of generating a design preferred by a user using a navigation map for a reference design.

### 2. Discussion of Related Art

With increases in living standards, there is a growing interest in design among people. In the past, products to be purchased were selected based on price or function, but recently, the significance of design has been increasing as a criterion for selecting products.

Alongside this, various technologies are being developed to support designers in their design, and recently, with the development of generative artificial intelligence (AI) technology, various studies have been conducted to utilize generative AI in the design field. In order to support designers in their design tasks, there is ongoing research on a method of providing a variety of designs generated using generative AI to a designer.

As related art documents, there are disclosed a patent document, Korean Patent Registration No. 10-2316079, and a non-patent document, “SALAD: Part-Level Latent Diffusion for 3D Shape Generation and Manipulation, Juil Koo, Seungwoo Yoo, Minh Hieu Nguyen, Minhyuk Sung; Proceedings of the IEEE/CVF International Conference on Computer Vision (ICCV), 2023, pp. 14441-14451.”

### SUMMARY

The present disclosure is directed to providing a method of generating a design that is capable of supporting easy exploration of designs for a user to search for a design preferred by the user among reference designs, and generating a design preferred by the user.

According to an aspect of the present disclosure, there is provided a method of generating a design based on preference of a user, the method including: generating a navigation map for reference designs, the navigation map including points corresponding to latent vectors of the reference designs; estimating design preference of the user using a point selected by the user on the navigation map; and generating a design based on the design preference.

According to another aspect of the present disclosure, there is provided a method of providing a navigation map for design generation, the method including: generating latent vectors for reference designs using a pre-trained auto-encoder model; generating a navigation map for the reference designs, the navigation map including points corresponding to the latent vectors; and updating the navigation map according to design preference of a user.

According to another aspect of the present disclosure, there is provided a method of generating a design based on preference of a user, the method including: generating a navigation map for reference designs, the navigation map including points corresponding to latent vectors of the reference designs; generating a design based on design preference of the user; and providing the user with the navigation map and the generated design through a design generation interface, wherein the design generation interface includes: a design input window configured to receive a desired design from the user; a navigation map window in which the navigation map is displayed; and a design display window in which the generated design is displayed.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a diagram illustrating a system for generating a design based on user preference according to an embodiment of the present disclosure;

FIG. 2 is a diagram illustrating an auto-encoder model according to an embodiment of the present disclosure;

FIG. 3 is a diagram for describing a method of generating a design based on user preference according to an embodiment of the present disclosure;

FIG. 4 is a diagram for describing a navigation map according to an embodiment of the present disclosure;

FIG. 5 is a diagram for describing a method of providing a navigation map for design generation according to an embodiment of the present disclosure;

FIG. 6 is diagrams for describing a method of updating a navigation map according to an embodiment of the present disclosure; and

FIG. 7 and FIG. 8 are diagrams for describing a method of generating a design based on user preference according to another embodiment of the present disclosure.

### DETAILED DESCRIPTION OF EXEMPLARY EMBODIMENTS

While embodiments according to the concept of the present disclosure are subject to various modifications and alternative forms, specific embodiments thereof are shown by way of example in the accompanying drawings and will herein be described in detail. However, it should be understood that there is no intent to limit the present disclosure to the particular forms disclosed, rather the present disclosure is to cover all modifications, equivalents, and alternatives falling within the spirit and scope of the present disclosure. In the drawings, like numerals refer to like elements in description of each figure.

Hereinafter, embodiments according to the present disclosure will be described in detail with reference to the accompanying drawings.

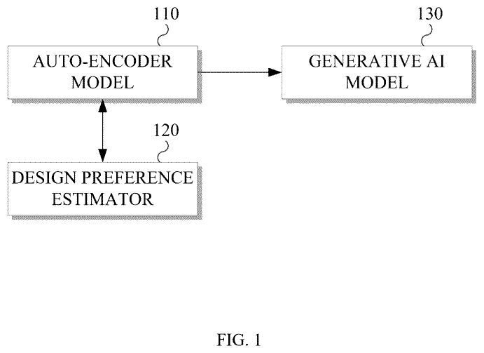

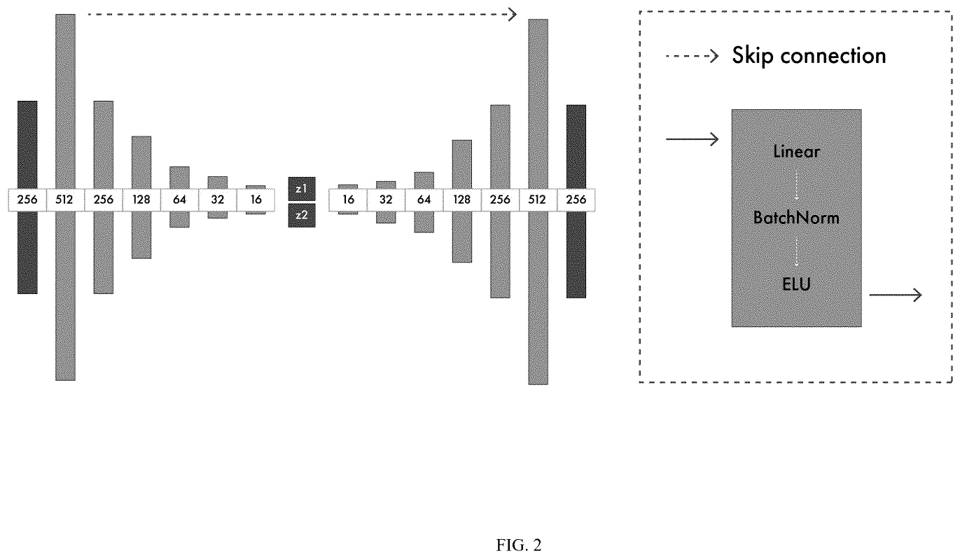

FIG. 1 is a diagram illustrating a system for generating a design based on user preference according to an embodiment of the present disclosure, and FIG. 2 is a diagram illustrating an auto-encoder model according to an embodiment of the present disclosure.

Referring to FIG. 1, a system for generating a design according to an embodiment of the present disclosure includes an auto-encoder model 110, a design preference estimator 120, and a generative AI model 130.

The auto-encoder model 110 is a neural network model, composed of an encoder and a decoder, that is trained to generate latent vectors for reference designs.

A reference design corresponds to a product design to be generated by the system for generating a design. For example, when the design to be generated by the system for generating a design is a design for a chair, the auto-encoder model 110 generates latent vectors for various reference designs for a chair. A latent vector is a vector containing a feature for a reference design, and the reference designs may include various types of product designs.

According to embodiments, the auto-encoder model 110 may receive an input of a reference design and generate a latent vector, or may receive an input of a high-dimensional latent vector for a reference design and generate a low-dimensional latent vector. As an example, the auto-encoder model 110 may generate a latent vector using a variational auto-encoder (VAE) model as shown in FIG. 2. The VAE model shown in FIG. 2 is a model that receives a 256-dimensional latent vector and generates a 2-dimensional latent vector (z1, z2), and may use batch normalization BatchNorm and an exponential linear unit (ELU) activation function.

The design preference estimator 120 may estimate design preference of a user through a user's design task and provide the estimated preference to the auto-encoder model 110. The latent vectors described above may be provided to the user in the form of a navigation map, and the design preference estimator 120 may estimate the design preference of the user using information about a latent vector selected by the user in the navigation map or information about a design requested by the user to be generated. The design preference estimator 120 periodically updates the design preference of the user during a user's design task process.

The design preference estimator 120 may estimate the design preference of the user using various preference estimation algorithms. As an example, a preferential Bayesian optimization algorithm based on the Bradley-Terry-Luce model may be used.

A latent vector selected based on design preference is input to the generative AI model 130, and the generative AI model 130 generates a design from the input latent vector. When the selected latent vector includes a plurality of selected latent vectors, the generative AI model 130 may synthesize the plurality of selected latent vectors to generate a synthesized design.

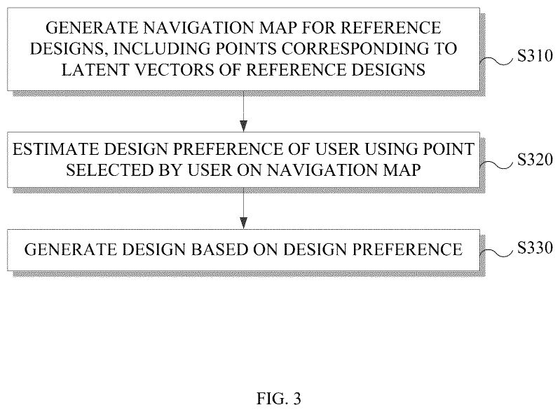

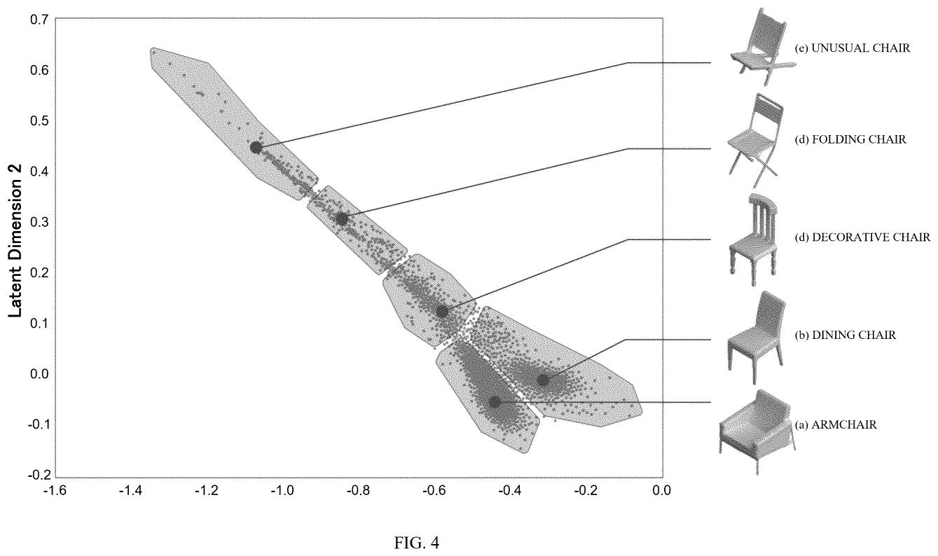

FIG. 3 is a diagram for describing a method of generating a design based on user preference according to an embodiment of the present disclosure, and FIG. 4 is a diagram for describing a navigation map according to an embodiment of the present disclosure.

The method of generating a design according to an embodiment of the present disclosure may be performed by a computing device including a memory and a processor, and the above-described system for generating a design may be an example of the computing device.

Referring to FIG. 3, the computing device according to an embodiment of the present disclosure generates a navigation map for reference designs that includes points corresponding to latent vectors of the reference designs (S310). As described above, the computing device may generate latent vectors for reference designs using a pre-trained auto-encoder model. In addition, the computing device may input a high-dimensional latent vector for a reference design into the auto-encoder model to obtain a low-dimensional latent vector. That is, the computing device may lower the dimensionality of an input latent vector and output a latent vector with a lowered dimension.

In FIG. 4, a view of a chair design being used as a reference design and a navigation map generated from two-dimensional latent vectors is illustrated, and each point corresponds to a latent vector. The x-axis (Latent Dimension 1) and y-axis (Latent Dimension 2) of the navigation map implemented in a two-dimensional space correspond to two elements of the two-dimensional latent vector, and the values of the two elements of the latent vector may be mapped to the x-axis and y-axis of the navigation map. Referring to FIG. 3, points corresponding to latent vectors may be clustered and distributed by similar design categories in the navigation map. In FIG. 4, an embodiment in which latent vectors generated from reference designs for an unusual chair, a folding chair, a decorative chair, a dining chair, and an armchair are clustered and distributed on the navigation map according to design categories of an unusual chair, a folding chair, a decorative chair, a dining chair, and an armchair is illustrated.

The generated navigation map may be provided to the user, and the user may efficiently explore a preferred design through the navigation map. Since a complex design space composed of reference designs is converted into a navigation map of a 2D space through low-dimensional latent vectors, users may efficiently and intuitively explore their preferred designs.

Referring again to FIG. 3, the computing device estimates the design preference of the user using a point selected by the user on the navigation map (S320). As an example, when the user selects a point corresponding to a folding chair design, the computing device may estimate that the user prefers a folding chair design.

The computing device generates a design based on the design preference estimated in operation S320 (S330) and provides the generated design to the user. As an example, when it is estimated that the user prefers a folding chair design among chair designs, the computing device may sample a point corresponding to the folding chair design on the navigation map. Then, the computing device may input a latent vector for the sampled folding chair design into the generative AI model to generate a design for a folding chair.

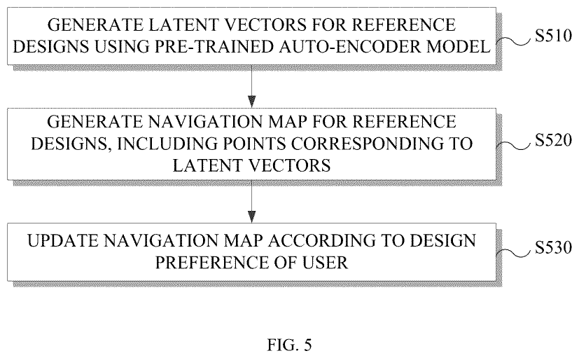

The computing device updates the navigation map according to design preference of the user, and a method of updating the navigation map is described in detail in FIG. 5.

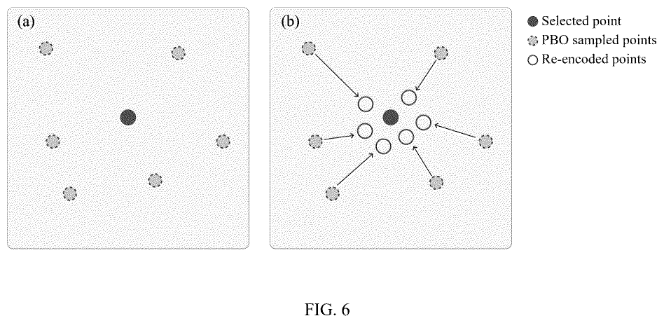

FIG. 5 is a diagram for describing a method of providing a navigation map for design generation according to an embodiment of the present disclosure, and FIGS. 6A and 6B are diagrams for describing a method of updating a navigation map according to an embodiment of the present disclosure.

Referring to FIG. 5, the computing device according to an embodiment of the present disclosure generates latent vectors for reference designs using a pre-trained auto-encoder model (S510). Then, the computing device generates a navigation map for the reference designs that includes points corresponding to the latent vectors (S520), and updates the navigation map according to design preference of a user (S530).

In operation S530, the computing device may update the navigation map by adjusting the color of the point according to design preference. As an example, the computing device may adjust the color of a point estimated to have high design preference on the navigation map to a dark color, and adjust the color of a point estimated to have low design preference to a light color.

Alternatively, the computing device may update the navigation map by adjusting the position of the point according to design preference. The computing device may sample at least one point on the navigation map according to design preference and adjust the position of the sampled at least one point to update the navigation map.

Referring to (a) of FIG. 6, when the user selects a point on the navigation map, the computing device may estimate a design corresponding to the selected point as a design preferred by the user and sample points around the selected point. As described above, because points of the navigation map are clustered by design categories, the points around the selected point may also be considered to correspond to the user's preferred design. Alternatively, the computing device may sample points included in the same design category as the design category of the point selected by the user.

Then, the computing device decodes a latent vector corresponding to the sampled point using the auto-encoder model, re-encodes the decoded latent vector using the auto-encoder model, and maps the re-encoded latent vector to the navigation map. That is, the computing device updates the positions of the existing sampled points (PBO sampled points) to the positions of points corresponding to latent vectors obtained through the re-encoding process (re-encoded points), as shown in (b) of FIG. 6, to thereby adjust the positions of the sampled points.

Meanwhile, according to embodiments, the computing device may synthesize a design corresponding to a latent vector selected by the user and provide the synthesized design to the user. In this case, the design having been used for the synthesis may not be used to estimate design preference. In addition, the design for the latent vector having been sampled during the current navigation map update process may also not be used to estimate design preference. With such a method, the computing device may be prevented from continuously and repeatedly sampling the same point on the navigation map.

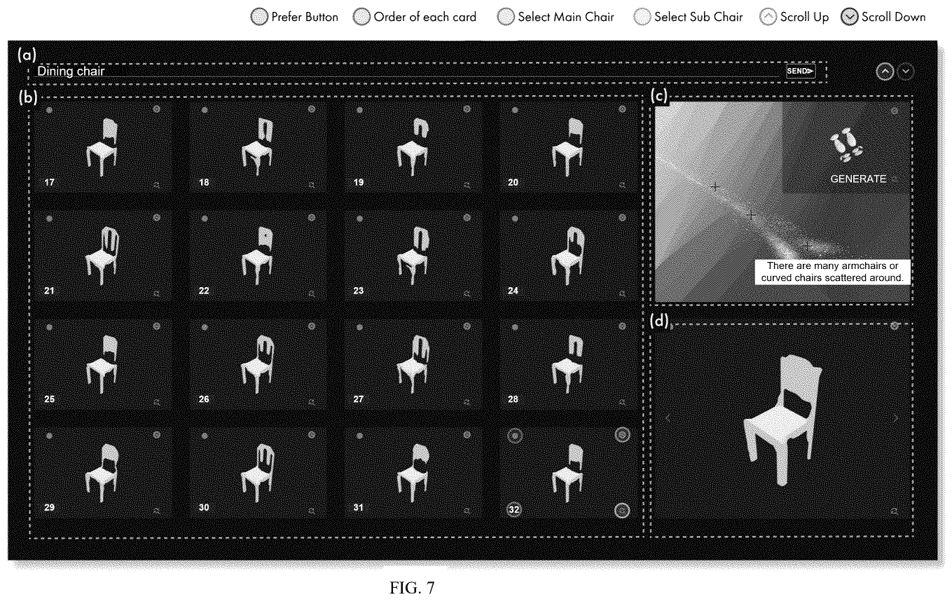

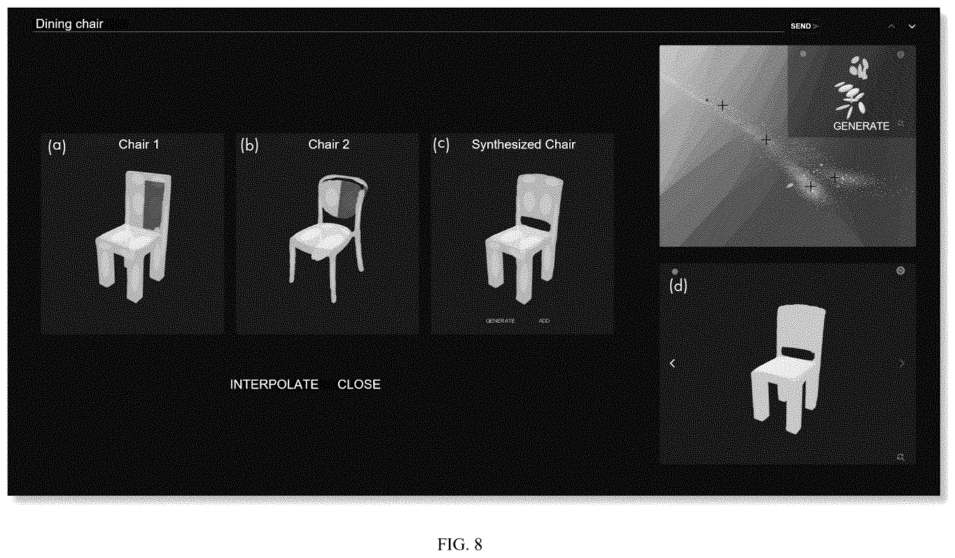

FIG. 7 and FIG. 8 are diagrams for describing a method of generating a design based on user preference according to another embodiment of the present disclosure.

As described above, the computing device may generate a navigation map for reference designs that includes points corresponding to latent vectors of the reference designs, and generate a design based on design preference of a user. In addition, the computing device may provide the user with the generated navigation map and design through a design generation interface as shown in FIG. 7.

The design generation interface according to the embodiment of the present disclosure includes a design input window as shown in (a) of FIG. 7, a navigation map window as shown in (c) of FIG. 7, and design display windows as shown in (b) and (d) of FIG. 7.

The design input window shown in (a) of FIG. 7 receives a desired design from the user. The user may enter a design desired to be generated in a text format into the design input window shown in (a) of FIG. 7.

The navigation map window shown in (c) of FIG. 7 displays a navigation map. The user may select a point on the navigation map for which the user desires to generate a design. The computing device may estimate design preference from the design input through the design input window shown in (a) of FIG. 7 or the point selected by the user on the navigation map, and the navigation map may be updated according to design preference of the user.

The design display windows shown in (b) and (d) of FIG. 7 display designs generated by the computing device, and when the user presses a scroll down button, the designs displayed in the design display windows shown in (b) and (d) of FIG are updated according to updated design preference.

The design display windows include a first display window shown in (b) of FIG. 7 and a second display window shown in (d) of FIG. 7. The first display window shown in (b) of FIG. 7 displays a design for which generation is requested by the user through the design input window shown in (a) of FIG. 7 or a design corresponding to a point selected on the navigation map, and the second display window shown in (d) of FIG. 7 displays a synthesized design of designs selected by the user. A synthesized design may be generated by the user selecting at least two designs, the design displayed in the first display window shown in (b) of FIG. 7 and the design corresponding to the point displayed on the navigation map.

When the user requests generation of a synthesized design, selected designs (see (a), (b), and (c) of FIG. 8) and a synthesized design (see (d) of FIG. 8) may be displayed.

The technical details described above can be implemented in the form of program instructions executable by a variety of computer devices and may be recorded on a computer readable medium. The computer readable medium may include, alone or in combination, program instructions, data files and data structures. The program instructions recorded on the computer readable medium may be specially designed and configured for the present disclosure or may be usable by a skilled person in the field of computer software. Computer readable record media include magnetic media such as a hard disk, a floppy disk, or a magnetic tape, optical media such as a compact disc read only memory (CD-ROM) or a digital video disc (DVD), magneto-optical media such as floptical disks, and hardware devices such as a ROM, a random-access memory (RAM), or a flash memory specially designed to store and execute programs. Examples of the program instructions include not only machine language code made by a compiler but also high level code that can be used by an interpreter etc., which is executed by a computer. The hardware device may be configured to act as one or more software modules in order to perform the operations of the present disclosure, or vice versa.

As is apparent from the above, according to an embodiment of the present disclosure, a complex design space including reference designs is converted into a navigation map of a 2D space through a low-dimensional latent vector, thereby allowing a user to efficiently and intuitively search for a preferred design through the navigation map.

In addition, according to an embodiment of the present disclosure, the navigation map is updated according to user preference, thereby allowing the user's design direction to be clearly identified.

In addition, according to an embodiment of the present disclosure, a user is provided with an interface that integrates functions of generating and synthesizing designs, and providing a navigation map, thereby efficiently supporting users in their design tasks.

While the disclosure has been shown and described with respect to particulars, such as specific components, embodiments, and drawings, the embodiments are used to aid in the understanding of the present disclosure rather than limiting the present disclosure, and those skilled in the art should appreciate that various changes and modifications are possible without departing from the spirit and scope of the disclosure. Therefore, the spirit of the present disclosure is not defined by the above embodiments but by the appended claims of the present disclosure, and the scope of the present disclosure is to cover not only the following claims but also all modifications and equivalents derived from the claims.

What is claimed is:

1. A method of generating a design based on preference of a user, the method comprising:
generating a navigation map for reference designs, the navigation map including points corresponding to latent vectors of the reference designs;
estimating design preference of the user using a point selected by the user on the navigation map; and
generating a design based on the design preference.

2. The method of claim 1, wherein the generating of the navigation map includes
generating the latent vectors for the reference designs using a pre-trained auto-encoder model.

3. The method of claim 2, wherein the generating of the navigation map includes
inputting a high-dimensional latent vector for the reference designs into the auto-encoder model to obtain the latent vectors in a low dimension.

4. The method of claim 2, further comprising:
sampling at least one point on the navigation map according to the design preference; and
adjusting a position of the sampled at least one point to update the navigation map.

5. The method of claim 4, wherein the updating of the navigation map includes
decoding a latent vector corresponding to the sampled point using the auto-encoder model; and
encoding the decoded latent vector using the auto-encoder model, and mapping the encoded latent vector to the navigation map.

6. The method of claim 4, wherein the sampling of the at least one point includes
sampling points surrounding the point selected by the user or points included in the same design category as a design category of the point selected by the user.

7. A method of providing a navigation map for design generation, the method comprising:
generating latent vectors for reference designs using a pre-trained auto-encoder model;
generating a navigation map for the reference designs, the navigation map including points corresponding to the latent vectors; and
updating the navigation map according to design preference of a user.

8. The method of claim 7, wherein the updating of the navigation map includes
sampling at least one point on the navigation map according to the design preference; and
adjusting a position of the sampled at least one point to update the navigation map.

9. The method of claim 8, wherein the updating of the navigation map includes
decoding a latent vector corresponding to the sampled point using the auto-encoder model; and
encoding the decoded latent vector using the auto-encoder model, and mapping the encoded latent vector to the navigation map.

10. The method of claim 7, wherein the updating of the navigation map includes
adjusting a color of the points depending on the design preference.

11. A method of generating a design based on preference of a user, the method comprising:
generating a navigation map for reference designs, the navigation map including points corresponding to latent vectors of the reference designs;
generating a design based on design preference of the user; and
providing the user with the navigation map and the generated design through a design generation interface,
wherein the design generation interface includes:
a design input window configured to receive a desired design from the user;
a navigation map window in which the navigation map is displayed; and
a design display window in which the generated design is displayed.

12. The method of claim 11, further comprising:
estimating design preference from a design entered through the design input window or a point selected by the user on the navigation map.

13. The method of claim 11, wherein the design display window displays a synthesized design of a design selected by the user, and
the design selected by the user includes at least two designs among a design displayed in the design display window and a design corresponding to the point displayed on the navigation map.
